(19) United States
(12) Patent Application Publication
(10) Pub. No.: US 2025/0126786 A1
(43) Pub. Date: Apr. 17, 2025

(54) FABRICATING FILLING STRUCTURES IN THREE-DIMENSIONAL SEMICONDUCTIVE DEVICES

(71) Applicant: Yangtze Memory Technologies Co., Ltd., Wuhan (CN)

(72) Inventors: Jiyue SONG, Wuhan (CN); Zongke XU, Wuhan (CN); Qiangwei ZHANG, Wuhan (CN); Wei XU, Wuhan (CN); Jiajia WU, Wuhan (CN)

(21) Appl. No.: 18/518,399

(22) Filed: Nov. 22, 2023

Related U.S. Application Data
(63) Continuation of application No. PCT/CN2023/124742, filed on Oct. 16, 2023.

(51) Int. Cl. H10B 43/27; H10B 43/10

(52) U.S. Cl. CPC H10B 43/27; H10B 43/10

(57) ABSTRACT

Systems, devices, and methods for fabricating filling structures in three-dimensional (3D) semiconductor devices are provided. In one aspect, a semiconductor device includes: a semiconductor structure including a stack of conductive layers and isolating layers alternating with each other along a first direction. The semiconductor structure includes an array region and a connection region adjacent to the array region in a second direction perpendicular to the first direction. The semiconductor device further includes contact structures extending through at least a part of the connection region along the first direction. A conductive layer of the stack is coupled to a contact structure through a connection layer in the connection region. The conductive layer is in contact with the connection layer along the second direction. A filling film is in a space between a portion of the conductive layer and at least one isolating layer adjacent to the conductive layer.

### CROSS-REFERENCE TO RELATED APPLICATIONS

This application is a continuation of International Application No. PCT/CN2023/124742, filed on Oct. 16, 2023, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for fabricating filling structures in three-dimensional (3D) semiconductor devices.

One aspect of the present disclosure features a semiconductor device, including: a semiconductor structure including a stack of conductive layers and isolating layers alternating with each other along a first direction, where the semiconductor structure includes an array region and a connection region adjacent to the array region in a second direction perpendicular to the first direction; and contact structures extending through at least a part of the connection region along the first direction. A conductive layer of the stack is coupled to a contact structure of the contact structures through a connection layer in the connection region. The conductive layer is in contact with the connection layer along the second direction. A filling film is in a space between a portion of the conductive layer and at least one isolating layer adjacent to the conductive layer.

In some implementations, the semiconductor structure includes a corresponding liner layer between the conductive layer and two adjacent isolating layers including the at least one isolating layer. The filling film is in contact with the corresponding liner layer. A filling material of the filling film is different from a material of the corresponding liner layer.

In some implementations, the filling film includes TiN, and the corresponding liner layer includes TiN and a high-K dielectric material.

In some implementations, the connection layer includes a conductive material, and the filling film includes the conductive material.

In some implementations, the filling film includes an isolating material, and the isolating material includes a high-K dielectric material.

In some implementations, the high-K dielectric material includes at least one of aluminum oxide (Al₂O₃) or silicon nitride (SiN).

In some implementations, the filling film is in contact with an end of the connection layer along the second direction. The end of the connection layer includes a first surface in contact with the conductive layer and a second surface in contact with the filling film, the first surface and the second surface being offset along the second direction.

In some implementations, the contact structure includes at least one conductive layer and a body surrounded by the at least one conductive layer, and the connection layer is in contact with the at least one conductive layer at an end of the contact structure. The at least one conductive layer includes an inner layer in contact with the body and an outer layer in contact with the connection layer. The body includes an isolating material, the inner layer includes a metallic material, and the outer layer and the connection layer includes a same conductive material different from the metallic material.

In some implementations, one of the contact structures is coupled to two or more of the conductive layers in the stack, and where the one of the contact structures includes two or more conductive sections that are isolated from each other, and each of the two or more conductive sections is coupled to a respective one of the two or more of the conductive layers in the stack.

In some implementations, the semiconductor structure includes a plurality of dielectric layers and isolating layers alternating with each other along the first direction in the connection region. Each of the contact structures extends through a respective set of dielectric layers and isolating layers in the connection region, and the connection layer is between two adjacent isolating layers in the connection region.

Another aspect of the present disclosure features a method including: providing a semiconductor structure including a stack of conductive layers and isolating layers alternating with each other along a first direction, where the semiconductor structure includes an array region and a connection region adjacent to the array region in a second direction perpendicular to the first direction, and the semiconductor structure includes a plurality of dielectric layers and isolating layers alternating with each other along the first direction in the connection region; forming holes extending through at least a part of the connection region along the first direction; removing a portion of a dielectric layer of the plurality of dielectric layers in the connection region with a first etching rate, where the dielectric layer is coupled to a conductive layer in the stack; and removing a remaining portion of the dielectric layer with a second etching rate, where the second etching rate is smaller than the first etching rate.

In some implementations, removing the portion of the dielectric layer includes using a first etching solution through a hole corresponding to the dielectric layer. Removing the remaining portion of the dielectric layer includes using a second etching solution through the hole corresponding to the dielectric layer. The dielectric layer includes a sacrificial dielectric material, and where the second etching solution has a lower etching rate for the sacrificial dielectric material than the first etching solution.

In some implementations, each conductive layer of the conductive layers of the stack is coupled to a respective hole of the holes through a corresponding one of the plurality of dielectric layers in the connection region, and is in contact with the corresponding one of the plurality of dielectric layers along the second direction.

In some implementations, the semiconductor structure includes a corresponding liner layer between the conductive layer and two adjacent isolating layers. During removing the remaining portion of the dielectric layer using the second etching solution, a portion of the corresponding liner layer is etched to form a space between a portion of the conductive layer and at least one isolating layer of the two adjacent isolating layers. The corresponding liner layer includes a high-K dielectric material, where the second etching solution has a higher etching rate for the sacrificial dielectric material than for the high-K dielectric material.

In some implementations, the method further includes: filling a filling material through the hole into the space to form a filling film between the portion of the conductive layer and the at least one isolating layer adjacent to the conductive layer. The filling film is in contact with a remaining portion of the corresponding liner layer.

In some implementations, the filling material includes a conductive material. The method can further include: filling the filling material through the hole to form a connection layer in a region of the dielectric layer in the connection region and a first conductive layer on an inner surface of the hole, and forming a second conductive layer on the first conductive layer to form a contact structure corresponding to the hole.

In some implementations, the method further includes: forming a body of the contact structure on the second conductive layer to fill the hole.

In some implementations, the filling material includes an isolating material. The method can further include: etching the filling material through the hole to expose an end surface of the conductive layer.

In some implementations, during filling the filling material through the hole into the space to form the filling film, a filling layer is formed on an inner surface of the hole. The method can further include: etching the filling material to remove the filling layer. A portion of the filling film in the space between the portion of the conductive layer and the at least one isolating layer adjacent to the conductive layer is removed during etching the filling material.

In some implementations, the isolating material includes a high-K dielectric material or the sacrificial dielectric material.

In some implementations, the method further includes: forming a connection layer in the connection region in a region of the dielectric layer in the connection region, where the connection layer is in contact with the end surface of the conductive layer along the second direction and conductively coupled to the conductive layer, and the connection layer is between the two adjacent isolating layers in the connection region; and forming a contact structure corresponding to the hole by forming at least one conductive layer on an inner surface of the hole and on the connection layer.

In some implementations, forming the contact structure includes: forming a body of the contact structure on the at least one conductive layer in the hole by filling the isolating material in the hole. In some implementations, forming the at least one conductive layer includes: forming a first conductive layer on the inner surface of the hole and on the connection layer; and forming a second conductive layer on the first conductive layer. The body includes an isolating material, the second conductive layer includes a metallic material, and the first conductive layer and the connection layer includes a same conductive material different from the metallic material.

Another aspect of the present disclosure features a method, including: providing a semiconductor structure including a stack of conductive layers and isolating layers alternating with each other along a first direction, where the semiconductor structure includes an array region and a connection region adjacent to the array region in a second direction perpendicular to the first direction, and the semiconductor structure includes a plurality of dielectric layers and isolating layers alternating with each other along the first direction in the connection region; forming holes extending through at least a part of the connection region along the first direction; removing a dielectric layer of the plurality of dielectric layers in the connection region, where the dielectric layer is coupled to a conductive layer in the stack, and where, during removing the dielectric layer, a portion of a corresponding liner layer between the conductive layer and two adjacent isolating layers is etched to form a space between a portion of the conductive layer and at least one isolating layer of the two adjacent isolating layers; and filling a filling material through a hole corresponding to the dielectric layer into the space to form a filling film between the portion of the conductive layer and the at least one isolating layer adjacent to the conductive layer, where the filling film is in contact with a remaining portion of the corresponding liner layer.

In some implementations, each conductive layer of the conductive layers of the stack is coupled to a respective hole of the holes through a corresponding one of the plurality of dielectric layers in the connection region, and is in contact with the corresponding one of the plurality of dielectric layers along the second direction.

In some implementations, removing the dielectric layer of the plurality of dielectric layers in the connection region includes: removing, using a first etching solution and through a hole corresponding to the dielectric layer, a portion of the dielectric layer of the plurality of dielectric layers in the connection region; and removing, using a second etching solution through the hole, a remaining portion of the dielectric layer that is in contact with the conductive layer in the connection region, where the second etching solution has a lower etching rate for a sacrificial dielectric material in the dielectric layer than the first etching solution.

In some implementations, the corresponding liner layer includes a high-K dielectric material, where the second etching solution has a higher etching rate for the sacrificial dielectric material than for the high-K dielectric material.

In some implementations, the method further includes: forming a connection layer in the connection region in a region of the dielectric layer in the connection region, where the connection layer is in contact with an end surface of the conductive layer along the second direction and conductively coupled to the conductive layer, and the connection layer is between the two adjacent isolating layers in the connection region.

In some implementations, the filling material includes a conductive material. The method can further include: filling the filling material through the hole to form the connection layer in the region of the dielectric layer in the connection region and a first conductive layer on an inner surface of the hole, and forming a second conductive layer on the first conductive layer to form a contact structure corresponding to the hole.

In some implementations, the method further includes: forming a body of the contact structure on the second conductive layer to fill the hole.

In some implementations, the filling material includes an isolating material. The method can further include: etching the filling material through the hole to expose the end surface of the conductive layer.

In some implementations, during filling the filling material through the hole into the space to form the filling film, a filling layer is formed on an inner surface of the hole. The method can further include: etching the filling material to remove the filling layer, where a portion of the filling film in the space between the portion of the conductive layer and the at least one isolating layer adjacent to the conductive layer is removed during etching the filling material.

In some implementations, the isolating material includes a high-K dielectric material or the sacrificial dielectric material.

In some implementations, the method further includes: forming a contact structure corresponding to the hole by forming at least one conductive layer on an inner surface of the hole and on the connection layer.

In some implementations, forming the contact structure includes: forming a body of the contact structure on the at least one conductive layer in the hole.

In some implementations, forming the body of the contact structure includes filling an isolating material in the hole.

In some implementations, forming the at least one conductive layer includes: forming a first conductive layer on the inner surface of the hole and on the connection layer; and forming a second conductive layer on the first conductive layer.

In some implementations, the second conductive layer includes a metallic material, and the first conductive layer and the connection layer include a same conductive material different from the metallic material.

Implementations of the present disclosure can provide one or more of the following technical advantages and/or benefits. For example, the techniques enable to address a loss of a high-K dielectric material of a liner layer between a conductive layer and two adjacent isolating layers when forming a connection layer coupled to the conductive layer, e.g., by filling a filling material into a space due to the loss of the high-K dielectric material. With the filling material filled between the conductive layer and at least one of the two adjacent isolating layers, a breakdown voltage of a corresponding conductive layer (or transistor or a memory cell) can be increased, which can minimize or avoid electric leakage between channel structures and word lines. The filling material can include a high-K dielectric material (e.g., Al₂O₃), a sacrifice dielectric material (e.g., SiN), or any other suitable material having high resistance to electrical breakdown.

Further, the techniques provide a sequential etching scheme by etching a corresponding dielectric layer in contact with the conductive layer in two or more sequential steps, including a first step with a higher etching rate and a second or any other sequential step with a lower etching rate. For example, in the first step, a first etching solution (e.g. phosphoric acid) with a higher temperature can be used to etch a first portion of the dielectric layer with a first etching rate, and a second etching solution (e.g., phosphoric acid with one more additives) with a lower temperature can be used to etch a second portion (e.g., a remaining portion) of the dielectric layer with a second etching rate that is slower than the first etching rate. Moreover, the second etching solution can be configured to etch a material of the dielectric layer (e.g., SiN) faster than a material of the liner layer (e.g., high-K dielectric material). The sequential etching scheme and/or the choice of the etching solutions enables to create spaces (e.g., gaps or voids) between the conductive layer and the two adjacent isolating layers without bending, which enables the filling material to be filled into the spaces between both sides of the conductive layer and the two adjacent isolating layers to further increase the breakdown voltage. The techniques enable to omit the operation of first growing a stop layer and then removing the stop layer, which can also avoid a loss of an isolating material (e.g., oxide) of the adjacent isolating layers. The techniques also enable to increase a fabrication yield of semiconductor devices.

The techniques can be applied to any semiconductor structures or devices that are configured to avoid electric leakage or breakdown, e.g., between conductive layers or components. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a top view of an example 3D semiconductor structure.

FIG. 2A illustrates cross-sectional views of an example 3D semiconductor structure.

FIG. 2B illustrates cross-sectional views of another example 3D semiconductor structure.

FIGS. 3A and 3B illustrate an example 3D semiconductor structure, where FIG. 3A is a cross-sectional view of the example 3D semiconductor structure, and FIG. 3B is a top view of the example 3D semiconductor structure.

FIGS. 4A-4B illustrate cross-sectional views of example semiconductor structures at various stages of an example fabrication process.

FIGS. 5A-5E illustrate cross-sectional views of example semiconductor structures at various stages of another example fabrication process.

FIG. 6A illustrates a flow chart of an example process of forming a 3D semiconductor structure.

FIG. 6B illustrates a flow chart of another example process of forming a 3D semiconductor structure.

FIG. 7 illustrates a block diagram of an example system having one or more example semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

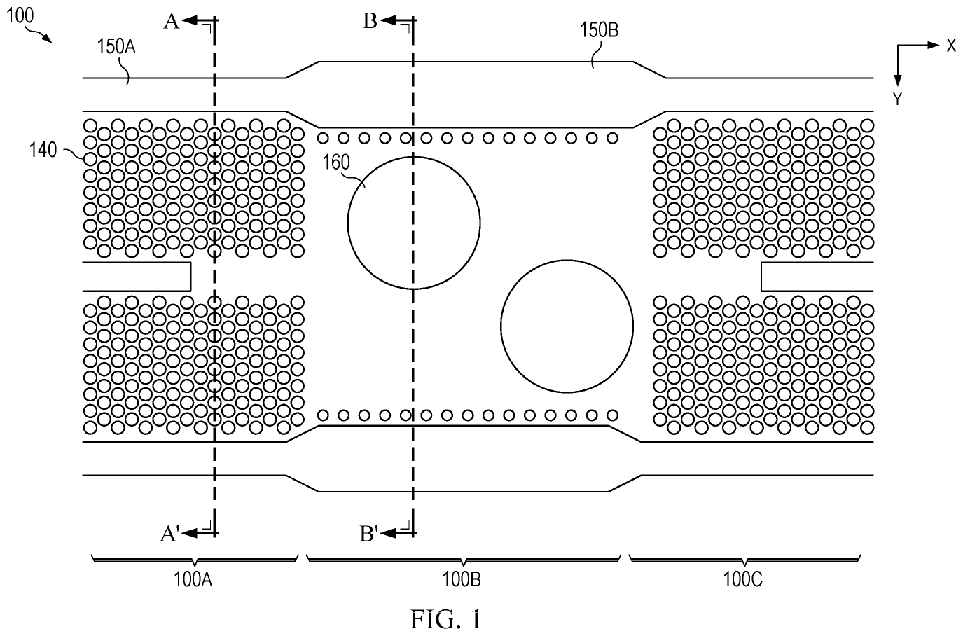

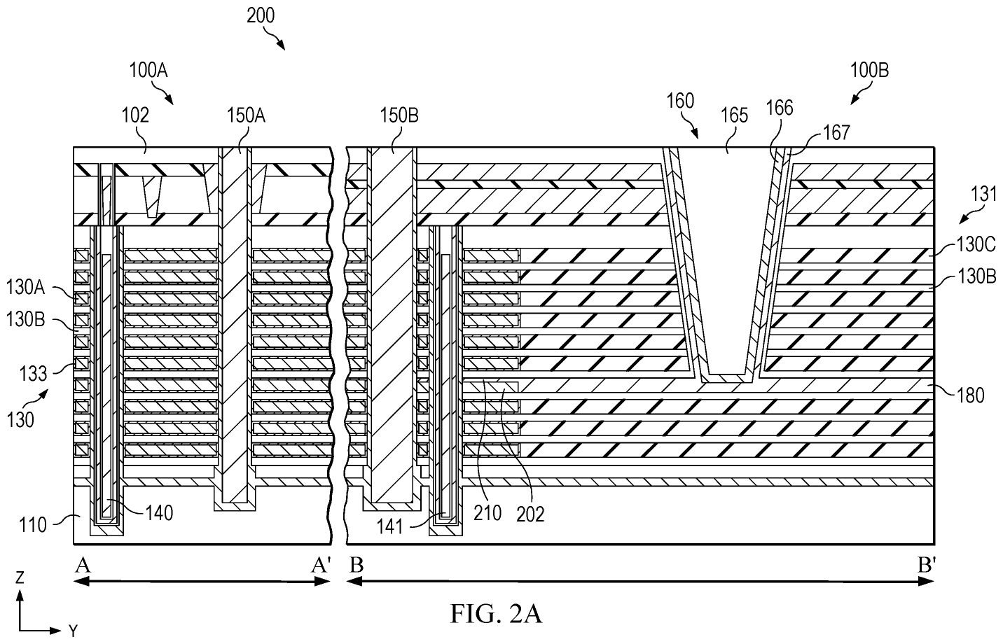

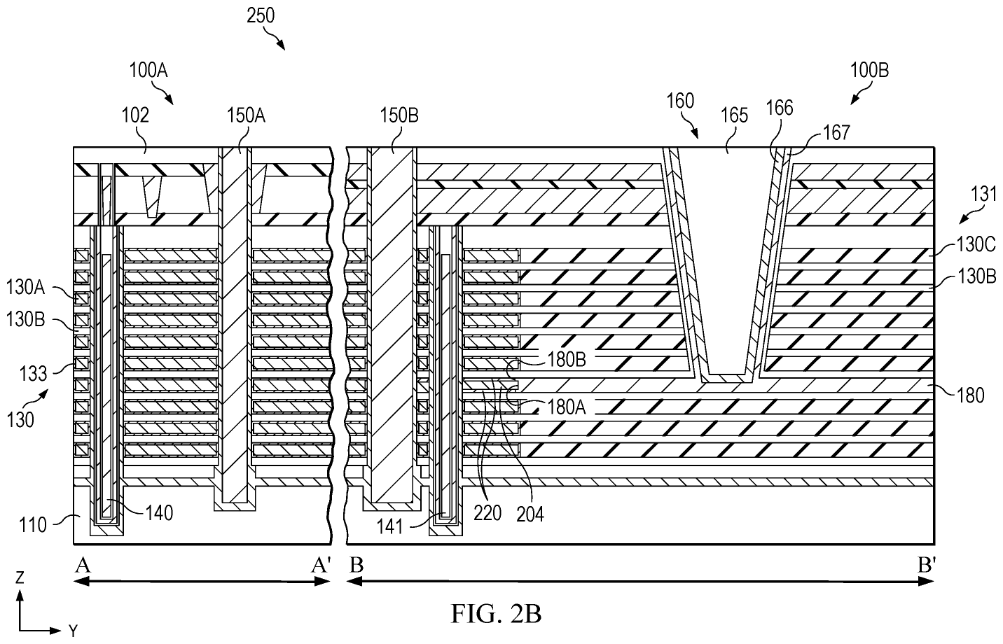

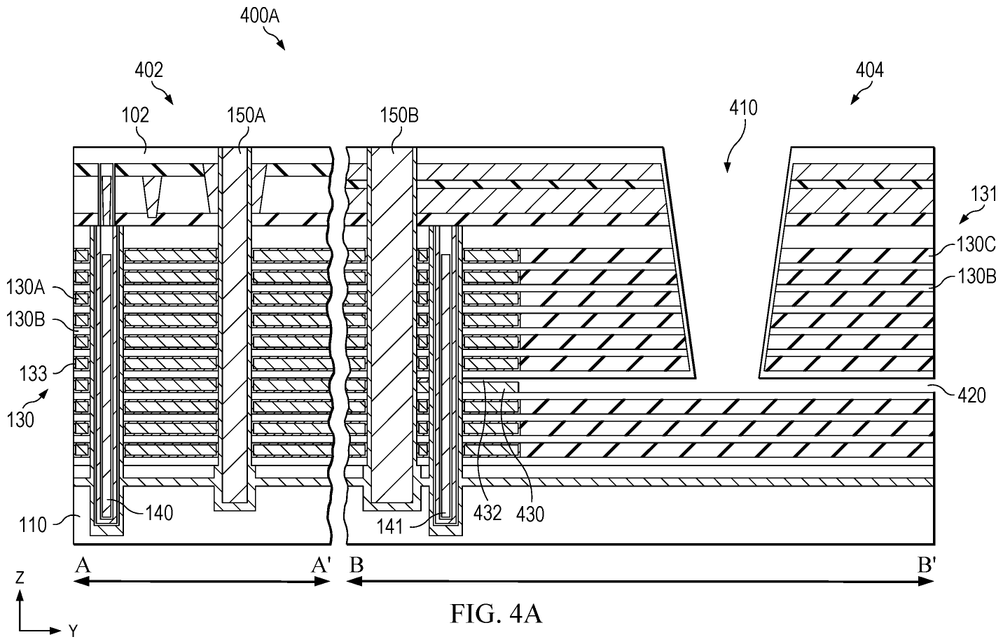

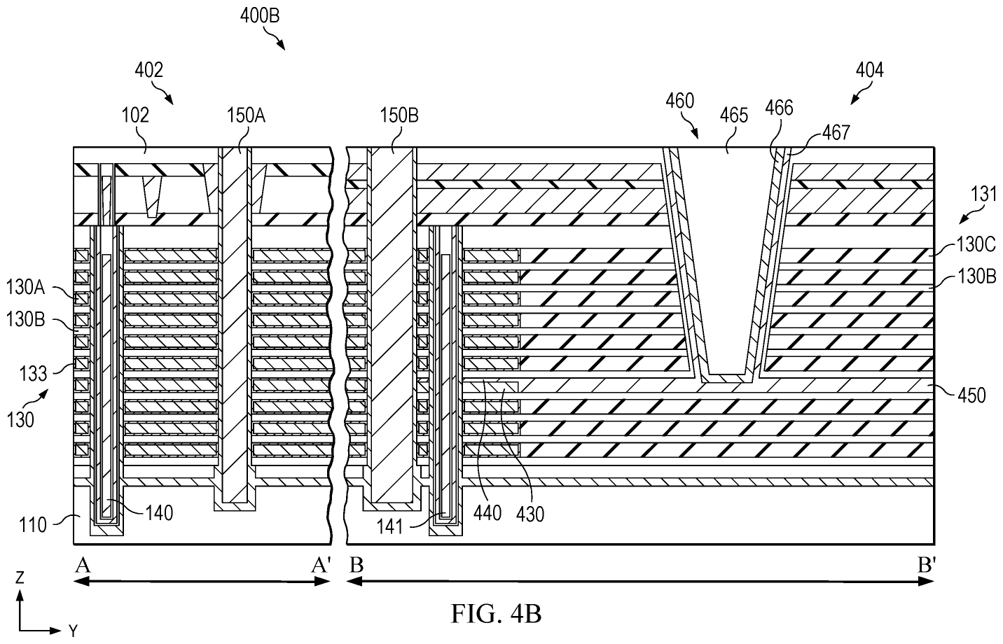

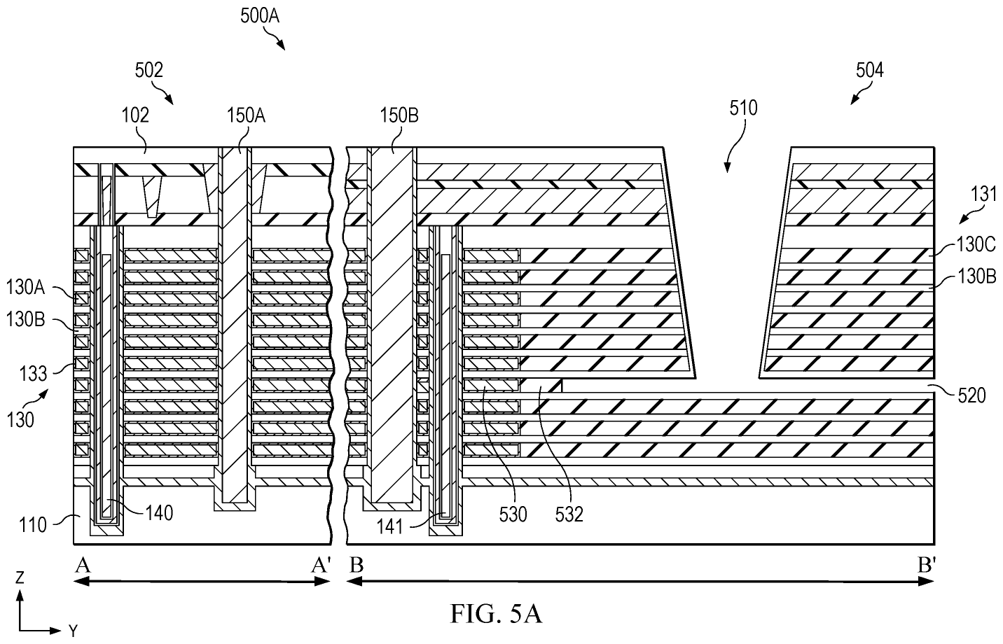

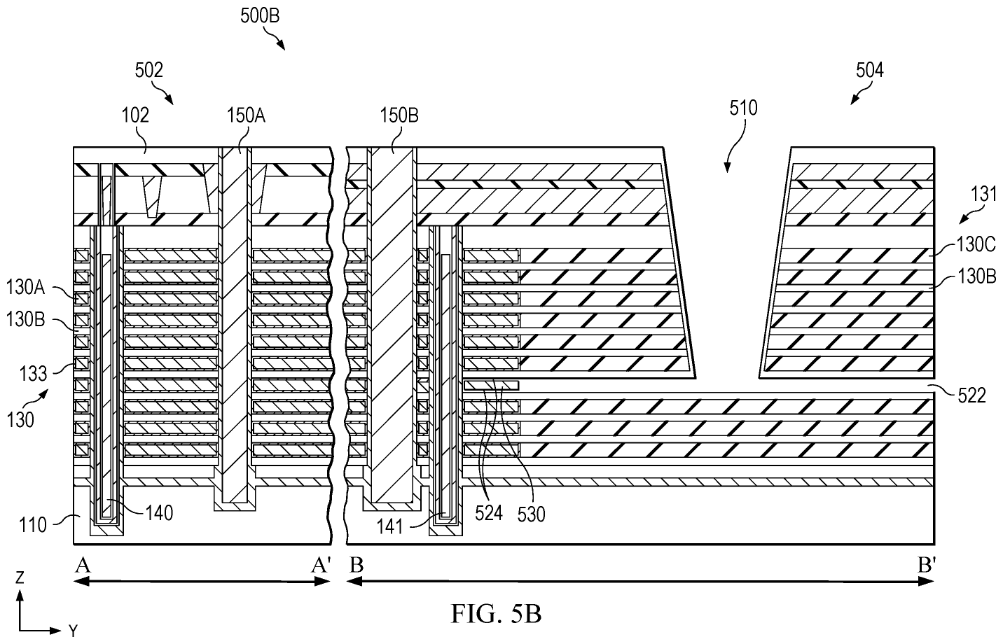

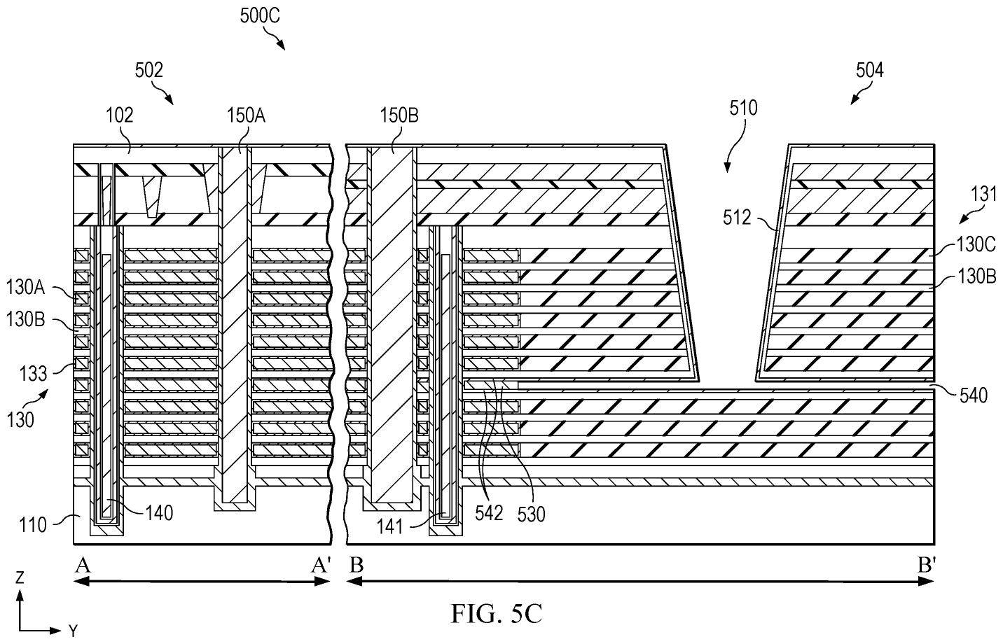

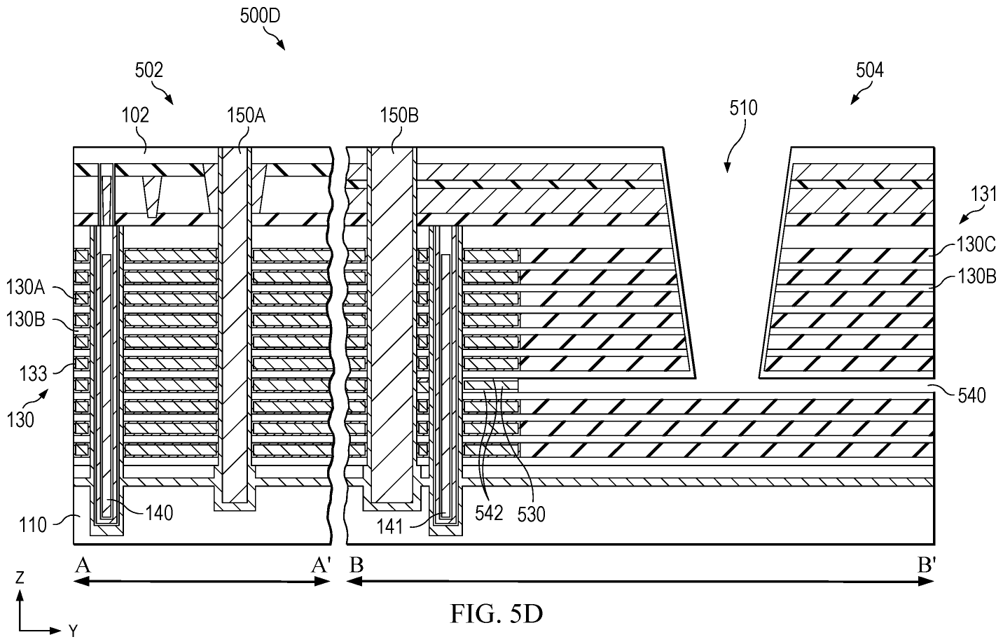

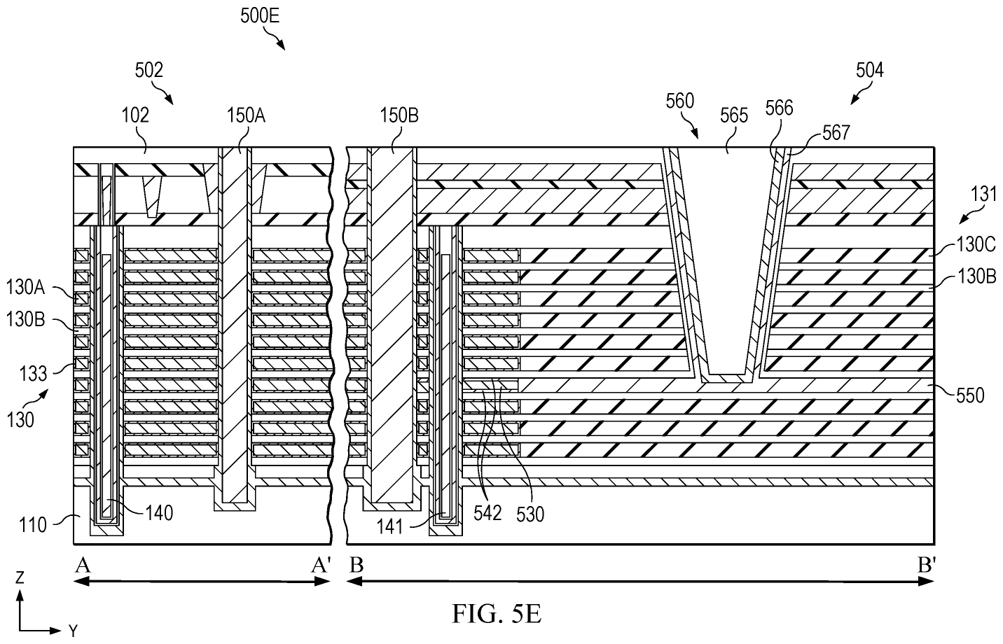

FIG. 1 illustrates a top view of an example 3D semiconductor structure 100. The 3D semiconductor structure 100 can be used to form a semiconductor device, e.g., a 3D NAND memory device. FIG. 2A illustrates cross-sectional views of an example 3D semiconductor structure 200 along cut lines AA′ and BB′ shown in FIG. 1 according to a first fabrication process as described with respect to FIGS. 4A-4B. The 3D semiconductor structure 200 can be same as, or similar to, the semiconductor structure 100 of FIG. 1. FIG. 2B illustrates cross-sectional views of another example 3D semiconductor structure 250 along cut lines AA′ and BB′ shown in FIG. 1 according to a second fabrication process as described with respect to FIGS. 5A-5E. The 3D semiconductor structure 250 can be same as, or similar to, the semiconductor structure 100 of FIG. 1.

In some implementations, as illustrated in FIG. 1, the semiconductor structure 100 includes one or more array regions and a connection region configured to provide conductive connections for the one or more array regions. In some examples, the semiconductor structure 100 includes two array regions 100A, 100C and a connection region 100B between the two array regions along a first horizontal direction (e.g., X direction). Each array region 100A, 100C includes an array of channel structures 140. A channel structure 140 can be used to form a string of memory cells that can be coupled in serial along a vertical direction (e.g., Z direction) perpendicular to the first horizontal direction. A memory cell can include at least one vertical transistor. The vertical transistors of the memory cells can be stacked together along the vertical direction. As illustrated in FIG. 1, contact structures 160 can be formed within the connection region 100B. A contact structure 160 can be configured to connect a corresponding one of the conductive layers within the array region 100A and/or array region 100C.

In some implementations, as illustrated in FIG. 2A or FIG. 2B, the semiconductor structure 200 or 250 includes a substrate 110 and a stack 130 of alternating conductive layers 130A and isolating layers 130B provided over the substrate 110. The substrate 110 can be any suitable semiconductor substrate having any suitable semiconductor materials, such as monocrystalline, polycrystalline or single crystalline semiconductors. For example, the substrate 110 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. The semiconductor structure 100 can include a top layer 102 made of an isolating material (e.g., oxide).

The stack 130 can extend in a second horizontal direction (e.g., Y direction) that is parallel to a top surface of the substrate 110 and perpendicular to the first horizontal direction. The conductive layers 130A and the isolating layers 130B can alternate in the vertical direction (e.g., Z direction) perpendicular to the second horizontal direction. The conductive layers 130A can be the same or different from each other in thickness, for example, ranging from 10-500 nm, e.g., about 35 nm. The isolating layers 130B can also be the same or different from each other in thickness, for example, ranging from 10-500 nm, e.g., about 25 nm. It should be noted that the number of the conductive layers 130A and the isolating layers 130B shown in FIG. 2A or 2B is for illustration only and that any suitable number of the conductive layers 130A and the isolating layers 130B can be included in the stack 130 of the semiconductor structure 200 or 250. The conductive layers 130A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 130B can include dielectric material, such as silicon oxide, silicon nitride, silicon oxynitride, or any combination thereof. In some implementations, the isolating layers 130B can also include high-k dielectric materials, such as hafnium oxide, zirconium oxide, aluminum oxide, tantalum oxide, lanthanum oxide, or any combination thereof.

In some implementations, as illustrated in FIG. 2A or FIG. 2B, the stack 130 includes liner layers 133. A liner layer 133 can cover part or all sides of a corresponding conductive layer 130A and be between the conductive layer 130A and two isolating layers 130B adjacent to the corresponding conductive layer 130A. The liner layer 133 can include a high-K dielectric material (e.g., Al₂O₃). In some examples, the conductive layer 130A includes a metallic material (e.g., W) and an adhesive material (e.g., TiN), and the adhesive material can be deposited between the metallic material and the high-K dielectric material. In some examples, the conductive layer 130A includes the metallic material (e.g., W), and the liner layer 133 includes the adhesive material (e.g., TiN) and the high-K dielectric material.

One or more channel structures can be formed in the stack 130 through the conductive layers 130A and the isolating layers 130B of the stack 130 into the substrate 110. For example, as shown in FIG. 2A or 2B, a first channel structure 140 is formed within the array region 100A, and a second channel structure 141 is formed within the connection region 100B. In some examples, each of the first and second channel structures 140 and 141 can be in the shape of a cylinder or a pillar, and can include a high-k layer, a block layer surrounded by the high-k layer, a charge trapping layer (or a storage layer) surrounded by the block layer, a tunneling layer surrounded by the charge trapping layer, a channel layer surrounded by the tunneling layer, and a core filler layer surrounded by the channel layer, which extend through the conductive layers 130A and the isolation layers 130B of the stack 130, and a channel contact formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-k dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide).

Each of the first and second channel structures 140 and 141 can be formed as follows: one or more channel openings are formed subsequently by a combination of a photolithography process and an etching process to extend through sacrificial layers (e.g., silicon nitride) of the stack 130 and the isolating layer 130B of the stack 130 down into the substrate 110; and the high-k layer, the block layer, the charge trapping layer, the tunneling layer, the channel layer, the core filler layer and the channel contact can be formed within the channel openings subsequently. In some implementations, the sacrificial layers of the stack 130 within the array region 100A can be replaced with a conductive material, such as tungsten (W), to form conductive layers 130A of the 3D semiconductor structure 200 or 250. The conductive layers 130A can be used to form a stack of transistors of memory cells that can form a vertical memory cell string along the first channel structure 140. The first channel structure 140 can be connected to one or more metal layers formed above the stack 130. In some implementations, the second channel structure 141 is a dummy channel structure and is used to support the conductive layers 130A and the isolation layers 130B of the stack 130 within the connection region 100B, and thus no metal layer is connected to the second channel structure 141.

In some implementations, e.g., as illustrated in FIG. 2A or 2B, one or more first slit structures 150A can be formed within the stack 130 of the array region 100A in the first horizontal direction (e.g., X direction) to divide the semiconductor structure 100, 200 or 250 into a plurality of semiconductor blocks. Similarly, one or more second slit structures 150B can be formed in the connection region 100B in the first horizontal direction, to divide the semiconductor structure 100, 200 or 250 into the plurality of semiconductor blocks. Corresponding first slit structure 150A and second slit structure 150B can be coupled to each other along the first horizontal direction, e.g., as illustrated in FIG. 1. In some implementations, along the second horizontal direction (e.g., the Y direction as depicted in FIG. 1), a width of the first slit structure 150A is smaller than a width of the second slit structure 150B. For example, a width of the second slit structure 150B can be approximately 1.5 to 2 times that of the first slit structure 150A. Each of the first slit structure(s) 150A and/or the second slit structure(s) 150B can extend through the stack 130 in the vertical direction (e.g., the Z direction) perpendicular to the first horizontal direction and the second horizontal direction, e.g., as illustrated in FIG. 2A or 2B.

In some implementations, a tetraethyl orthosilicate (TEOS) hard mask can be deposited over the stack 130 in a deposition process, e.g., a chemical vapor deposition (CVD) process. A photoresist layer can be applied over the TEOS hard mask and is patterned corresponding to trench locations within the stack 130. The stack 130 with the TEOS hard mask formed thereover can then be etched, whereby trench structures can be formed within the stack 130 to uncover the substrate 110 and lateral sides of the sacrificial layers and the isolating layers 130B of the stack 130 are exposed. The trench structures can then be filled with a trench filler material (e.g., polysilicon) to form the first slit structures 150A and/or the second slit structures 150B.

The stack 130 can be a first stack. In some implementations, as illustrated in FIG. 2A or 2B, the connection region 100B includes a second stack 131 of multiple dielectric layers 130C and isolating layers 130B alternating with each other along the vertical direction (e.g., Z direction). An isolating layer 130B in the second stack 131 and a corresponding isolating layer 130B in the stack 130 are one layer extending along the second horizontal direction (e.g., Y direction) in the array region 100A and the connection region 100B. A dielectric layer 130C in the second stack 131 can extend to be in contact with a corresponding conductive layer 130A in the stack 130. To fabricate the stack 130 and the second stack 131, a series of alternating dielectric layers 130C and isolating layers 130B can be first formed. Then, dielectric layers 130C in a region of the stack 130 can be etched away, e.g., through an opening formed in the position of the slit structure 150B, while dielectric layers 130C in the second stack 131 remain unchanged. Then, the liner layers 133 and the conductive layers 130A can be formed in replace of the dielectric layers 130C in the region of the stack 130 to form the stack 130.

As illustrated in FIG. 2A or 2B, one or more contact structures 160 can be formed within the connection region 100B and configured to connect the conductive layers 130A of the 3D semiconductor structure 100, 200, or 250, e.g., to a control circuit. In some implementations, the connection region 100B includes a top end and a bottom end that are opposite along the Z direction, and each contact structure 160 is coupled out to a conductive contact at the top end or the bottom end of the connection region 100B. Each of the contact structures 160 extends from the top end through at least a portion of the second stack 131, e.g., through a respective set of dielectric layers 130C and isolating layers 130B in the connection region 100B, to a corresponding connection layer 180 that is between two adjacent isolating layers 130B in the connection region 100B. In some implementations, a conductive layer 130A of the stack 130 is coupled to a corresponding contact structure 160 through a corresponding connection layer 180 in the connection region 100B. The conductive layer 130A is in contact with the connection layer 180 along the second horizontal direction (e.g., Y-direction in FIG. 2A or 2B).

In some implementations, e.g., as illustrated in FIG. 2A or 2B, the contact structure 160 includes at least one conductive layer and a body 165 surrounded by the at least one conductive layer, and the connection layer 180 is in contact with the at least one conductive layer at a bottom of the contact structure 160. The at least one conductive layer can include an inner layer 166 in contact with the body 165 and an outer layer 167 in contact with the connection layer 180. In some implementations, the body 165 includes an isolating material (e.g., oxide), the inner layer 166 includes a metallic material (e.g., W), and the outer layer 167 and the connection layer 180 includes the same conductive material (e.g., TiN) different from the metallic material. In some implementations, the body 165 can include a conductive material, which can be same as the inner layer 166 or different from the inner layer 166.

In some implementations, e.g., as illustrated in FIG. 2A and as discussed with further details in FIGS. 4A-4B, a filling film 210 is formed between a portion 202 of a conductive layer 130A connected to a corresponding connection layer 180 and an isolating layer 130B adjacent to the conductive layer 130A, e.g., on one side (e.g., an upper side) of the conductive layer 130A. The filling film 210 can have a first end in contact with a corresponding liner layer 133 in the stack 130 and a second end in contact with an end of the corresponding connection layer 180 along a second horizontal direction (e.g., Y direction in FIG. 2A). The corresponding liner layer 133 can be between the conductive layer 130A and the two isolating layers 130B adjacent to the conductive layer 130A in the stack 130, e.g., along the second horizontal direction. The corresponding connection layer 180 can be with two adjacent isolating layers 130B in the second stack 131 and be in contact with the contact structure 160.

A filling material of the filling film 210 can be different from a material of the liner layer 133. In some examples, the filling material of filling film 210 includes a metallic material (e.g., TiN), and the material of the liner layer 133 can include a high-K dielectric material (e.g., Al₂O₃) and/or a metallic material (e.g., TiN). The filling material of the filling film 210 can be same as a material of the connection layer 180, e.g., TiN. As described with further details in FIG. 4B, the filling film 210 and the connection layer 180 can be formed in one processing step.

In some implementations, e.g., as illustrated in FIG. 2B and as discussed with further details in FIGS. 5A-5E, a filling film 220 is formed between both sides of a portion 204 of a conductive layer 130A connected to a corresponding connection layer 180 and two isolating layers 130B adjacent to the conductive layer 130A, which is different from the filling film 210 formed between one side of the portion 202 of the conductive layer 130A and one adjacent isolating layer 130B as illustrated in FIG. 2A. That is to say, along the vertical direction, there is the filling film 220 formed on a top side of the portion 204 of the conductive layer 130A and there is also the filling film 220 formed on a lower side of the portion 204 of the conductive layer 130A. In this way, both sides of the portion 204 of the conductive layer 130A are separated and isolated from the two adjacent isolating layers 130B. A filling material of the filling film 220 can be different from a material of the liner layer 133. In some implementations, the filling film 220 includes an isolating material, for example, a high-K dielectric material such as aluminum oxide (Al₂O₃), or silicon nitride (SiN). Thus, the filling film 220 on both sides of the portion 204 of the conductive layer 130A, as shown in FIG. 2B, can increase a breakdown voltage of a conductive layer, a corresponding transistor, or a corresponding memory cell, which can avoid electric leakage.

As illustrated in FIG. 2B, the filling film 220 can have a first end in contact with a corresponding liner layer 133 in the stack 130 and a second end in contact with an end of the corresponding connection layer 180 along the second horizontal direction (e.g., Y direction in FIG. 2A). The corresponding liner layer 133 can be between the conductive layer 130A and the isolating layers 130B adjacent to the conductive layer 130A, e.g., along the second horizontal direction. The corresponding connection layer 180 can be with two adjacent isolating layers 130B in the second stack 131 and be in contact with the contact structure 160. In some implementations, an end of the connection layer 180 includes a first surface 180a in contact with the conductive layer 120A and a second surface 180b in contact with the filling film 220. The first surface 180a and the second surface 180b can be offset along the second horizontal direction. For example, the second surface 180b extends more to the filling film 220 than the first surface 180a to the portion 204 of the conductive layer 130A. The first surface 180a and the second surface 180b can form a step profile.

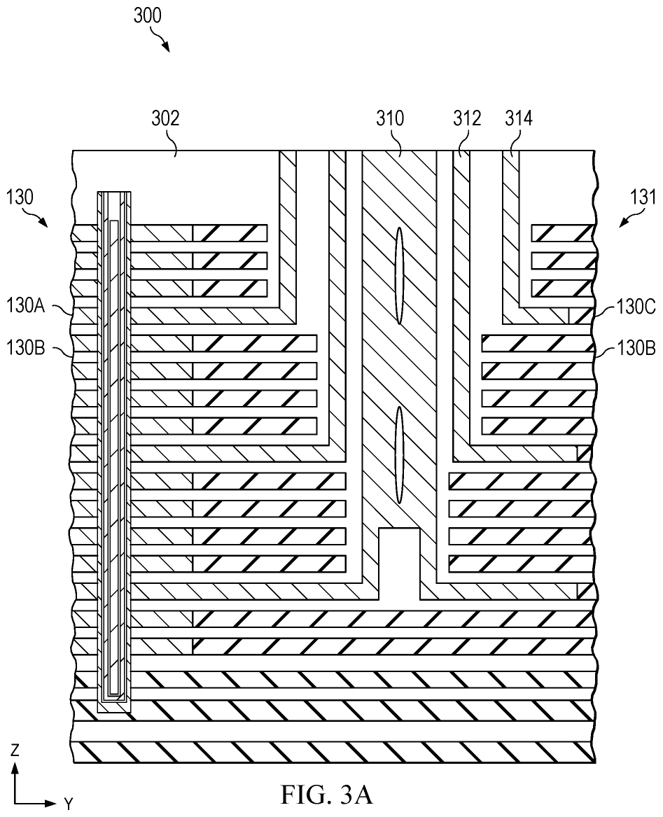

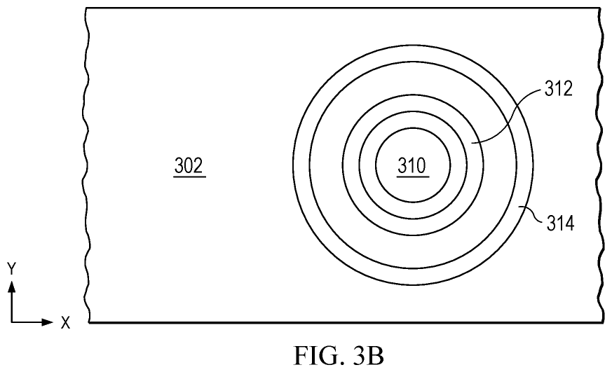

FIGS. 3A and 3B illustrate an example 3D semiconductor structure 300, where FIG. 3A is a cross-sectional view of the example 3D semiconductor structure 300, and FIG. 3B is a top view of the example 3D semiconductor structure 300. As shown in FIGS. 3A and 3B, each of contact structures 310, 312, and 314 is coupled to two or more of conductive layers 130A in a stack 130. Each of the contact structures 310, 312, 314 can have a circle or ring shape. In some implementations, e.g., as illustrated in FIG. 3B, the contact structure 310, 312, 314 can be positioned one surrounding another one, e.g., having a same center point. Adjacent contact structures 310 and 312, 312 and 314 can be separated from each other by an isolating material 302 (e.g., oxide). A contact structure with a smaller diameter, e.g., the contact structure 310 can extend deeper along the vertical direction in a connection region (e.g., the connection region 100B of FIGS. 1 and 2A-2B) than a contact structure with a larger diameter (e.g., the contact structure 312 or 314). The contact structures as illustrated in FIGS. 3A-3B can be implemented in the 3D semiconductor structure 100 of FIG. 1, 200 of FIG. 2A, and/or 250 of FIG. 2B.

FIGS. 4A to 4B illustrate an example process of fabricating a 3D semiconductor structure, e.g., the 3D semiconductor structure 200 as illustrated in FIG. 2A. Array region 402 in FIG. 4A or 4B is similar to, or same as, array region 100A or 100C in FIG. 1 or FIG. 2A, and connection region 404 in FIG. 4A or 4B is similar to the connection region 100B in FIG. 1 or FIG. 2A.

As shown in an example semiconductor structure 400a in FIG. 4A, in a first stage of the example process, one or more holes 410 are formed in the connection region 404. Each hole 410 extends through at least a part of the connection region 404 along a vertical direction (e.g., the Z direction in FIG. 4A) to a corresponding dielectric layer 130C in a second stack 131 including alternating dielectric layers 130C and isolating layers 130B in the connection region 404. The corresponding dielectric layer 130C is in contact with a conductive layer 130A in a first stack 130 including alternating conductive layers 130A and isolating layers 130B. The first stack 130 can also include a liner layer 133 formed between a conductive layer 130A and two adjacent isolating layers 130B.

The corresponding dielectric layer 130C in the connection region 404 is then removed through the hole 410, e.g., by an etching solution such as phosphoric acid, to form a space 420. As the liner layer 133 can include a high-K dielectric material, during removing the corresponding dielectric layer 130C, a portion of a corresponding liner layer 133 between the conductive layer 130A and two adjacent isolating layers 130B can be etched to form a space (e.g., a gap or void) 432 between a portion 430 (e.g., an end portion) of the conductive layer 130A and at least one isolating layer 130B of the two adjacent isolating layers 130B. In some cases, due to gravity, the portion 430 of the conductive layer 130A can bend to be in contact with a lower isolating layer 130B of the two adjacent isolating layers 130B, and the space 432 is formed between the portion 430 of the conductive layer 130A and an upper isolating layer 130B of the two adjacent isolating layers 130B. The portion 430 can be similar to, or same as, the portion 202 of FIG. 2A.

As shown in an example semiconductor structure 400b in FIG. 4B, in a second stage of the example process following the first stage, a filling material is filled through the hole 410 corresponding to the corresponding dielectric layer 130C into the space 432 to form a filling film 440 between the portion 430 of the conductive layer 130A and the upper isolating layer 130B adjacent to the conductive layer 130A. The filling film 440 can be similar to, or same as, the filling film 210 of FIG. 2A. The filling film 440 can be in contact with a remaining portion of the corresponding liner layer 133.

In some implementations, the second stage of the example process also includes forming a connection layer 450 in the space 420 in the connection region 404. The connection layer 450 can be between two adjacent isolating layers 130B in the connection region 101B or in the second stack 131. The connection layer 450 can be similar to, or same as, the connection layer 180 of FIG. 2A. The connection layer 450 can be in contact with an end surface of the portion 430 of the conductive layer 130A along the second horizontal direction and conductively coupled to the portion 430 of the conductive layer 130A.

In some implementations, the filling material includes a conductive material (e.g., TiN), and the second stage of the example process also includes filling the filling material through the hole 410 to form the connection layer 450 and an outer layer 467 (e.g., the outer layer 167 of FIG. 2A) on an inner surface of the hole 410. Further, an inner layer 466 (e.g., the inner layer 166 of FIG. 2A) is formed on a surface of the outer layer 467, and a body 465 is formed by filling an isolating material (e.g., oxide) in the hole 410 to form a contact structure 460 corresponding to the hole 410. In some implementations, the inner layer 466 includes a metallic material (e.g., W), and the outer layer 167 and the connection layer 180 include the same conductive material (e.g., TiN) different from the metallic material. The contact structure 460 can be same as, or similar to, the contact structure 160 of FIG. 1 or 2A. The semiconductor structure 400b in FIG. 4B can be similar to, or same as, the 3D semiconductor structure 200 as illustrated in FIG. 2A.

In some implementations, the filling material includes an isolating material (e.g., a high-K dielectric material Al₂O₃ or a dielectric material SiN). As described with further details in FIGS. 5C to 5E below, the filling material can be first filled into the space 432 to form a filling film (e.g., as illustrated in FIG. 5C). The filling material formed on the inner surface of the space 420 and the inner surface of the hole 410 can be then removed (e.g., as illustrated in FIG. 5D). Then, the connection layer 450 and the contact structure 460 can be formed as described with respect to FIG. 4B or 5E.

FIGS. 5A to 5E illustrate an example process of fabricating a 3D semiconductor structure, e.g., the 3D semiconductor structure 250 as illustrated in FIG. 2B. Array region 502 in each of FIGS. 5A to 5E can be same as, or similar to, array region 100A or 100C in FIG. 1 or 2B. Connection region 504 in each of FIGS. 5A to 5E can be same as, or similar to, connection region 100B of FIG. 1 or 2B.

As shown in an example semiconductor structure 500a in FIG. 5A, in a first stage of the example process, one or more holes 510 are formed in the connection region 504. Each hole 510 extends through at least a part of the connection region 504 along a vertical direction (e.g., the Z direction in FIG. 5A) to a corresponding dielectric layer 130C in a second stack 131 including alternating dielectric layers 130C and isolating layers 130B in the connection region 504. The corresponding dielectric layer 130C is in contact with a corresponding conductive layer 130A in a first stack 130 including alternating conductive layers 130A and isolating layers 130B. The first stack 130 can also include a liner layer 133 formed between a conductive layer 130A and two adjacent isolating layers 130B.

The corresponding dielectric layer 130C in the connection region 504 is then removed through the hole 510. Instead of removing completely the corresponding dielectric layer 130C, as illustrated in FIG. 5A, a first portion (e.g., a majority) of the corresponding dielectric layer 130C is first etched away with a first etching rate, and a second portion 532 of the corresponding dielectric layer 130C remains in contact with a corresponding liner layer 133 and a portion (e.g., an end portion) 530 of the corresponding conductive layer 130A. The portion 530 can be similar to, or same as, the portion 204 of FIG. 2B. The second portion 532 of the corresponding dielectric layer 130C can be a remaining portion of the corresponding dielectric layer 130C. In some implementations, removing the first portion of the corresponding dielectric layer 130C includes using a first etching solution through the hole 410 corresponding to the corresponding dielectric layer 130C.

As shown in the example semiconductor structure 500b in FIG. 5B, a second stage of the example process can include removing the second portion 532 of the corresponding dielectric layer 130C with a second etching rate. The second etching rate can be smaller than the first etching rate. The space 520 can be expanded to form a space 522 with the removal of the second portion 532 of the corresponding dielectric layer 130C.

As the liner layer 133 can include a high-K dielectric material, during removing the second portion 532 of the corresponding dielectric layer 130C, a portion of a corresponding liner layer 133, which is between the portion 530 of the corresponding conductive layer 130A and two adjacent isolating layers 130B and in contact with the second portion 532 of the corresponding dielectric layer 130C, can be etched to form a space (e.g., a gap or void) 524 between the portion 530 of the conductive layer 130A and at least one isolating layer 130B of the two adjacent isolating layers 130B, e.g., as illustrated in FIG. 5B.

In some implementations, removing the second portion 532 of the corresponding dielectric layer 130C includes using a second etching solution through the hole 410 corresponding to the corresponding dielectric layer 130C. The corresponding dielectric layer 130C can include a dielectric material (e.g., SiN), and the second etching solution can have a lower etching rate for the sacrificial dielectric material than the first etching solution. To reduce the etching of the liner layer 133 (e.g., high-K dielectric material such as Al₂O₃) while etching the second portion 532, the second etching solution can be configured to have a higher etching rate for the dielectric material than for the high-K dielectric material. That is, the second etching solution can have a high etching selection ratio for SiN versus high-K dielectric material. In such a way, the portion 530 of the corresponding conductive layer 130A can remain separated from the two adjacent isolating layers 130B, e.g., not bending down to be in contact with a lower isolating layer 130B, and spaces 524 can occur on an upper side and a lower side of the portion 530 of the corresponding conductive layer 130A, e.g., as illustrated in FIG. 5B. In some cases, after the first stage and the second stage of the example process, the corresponding dielectric layer 130C is removed sequentially with the first etching solution and the second etching solution, and the portion 530 of the corresponding conductive layer 130A may be in contact with the lower isolating layer 130B, e.g., similar to the portion 430 of the conductive layer 130A as illustrated in FIG. 4A.

In some examples, the first etching solution includes phosphoric acid, and etching the first portion of the corresponding conductive layer 130A can be performed with the first etching solution under a higher temperature (e.g., 150° C.). In contrast, the second etching solution can include phosphoric acid with one or more additives, and etching the second portion 532 of the corresponding conductive layer 130A can be performed with the second etching solution under a lower temperature (e.g., 120° C.).

As shown in the example semiconductor structure 500c in FIG. 5C, a third stage of the example process includes filling a filling material through the hole 410 into the spaces 524 between the portion 530 of the corresponding conductive layer 130A and two adjacent isolating layers 130B, which forms a filling film 542 between the portion 530 of the corresponding conductive layer 130A and the two adjacent isolating layers 130B. The formed filling film 542 is in contact with the remaining portion of the corresponding liner layer 133.

In some implementations, filling the filling material through the hole 510 also forms a layer 512 of the filling material on a surface of the semiconductor structure 500c, an inner surface of the hole 510, and an inner surface of the space 540. The layer 512 can be called as a filling layer. A deposition thickness of the filling material (or a thickness of the filling layer 152) can be greater (e.g., slightly) than a height of the space 524 along the vertical direction, such that the filling material can fully fill the spaces 524. In some examples, the deposition thickness is about 8 nm to 10 nm. In some examples, a height of the space 540 along the vertical direction is about 100 nm to 200 nm.

In some implementations, the filling material includes an isolating material, e.g., a high-K dielectric material (such as Al₂O₃), a sacrificial dielectric material (such as SiN), or any other suitable materials that have high resistance to electric breakdown. The filling material can be same as a material of the liner layer 133 (e.g., a high-K dielectric material). Filling the isolating material between the portion 530 of the corresponding conductive layer 130A and two adjacent isolating layers 130B can increase a breakdown voltage of a conductive layer, a corresponding transistor, or a corresponding memory cell, which can avoid electric leakage.

As shown in an example semiconductor structure 500d in FIG. 5D, a fourth stage of the example process includes: etching the filling material through the hole 510 to remove the layer 512 of the filling material to expose end surfaces of the filling film 542 that is filled between the portion 530 of the corresponding conductive layer 130A and the two adjacent isolating layers 130B. During etching the filling material, an end portion of the filling film 542 may also be etched to form a recess between the portion 530 and the two adjacent isolating layers 130B, e.g., as illustrated in FIG. 5D.

As shown in an example semiconductor structure 500e in FIG. 5E, a fifth stage of the example process includes depositing a conductive material (e.g., TiN) to form a connection layer 550 in the space 540 and between the two adjacent isolating layers 130B in the connection region 504. The connection layer 550 can be same as, or similar to, the connection layer 180 of FIG. 2B.

Along the second horizontal direction (e.g., Y direction), a first end surface of the connection layer 550 can be in contact with an end surface of the corresponding conductive layer 130A, and second end surfaces of the connection layer 550 can be in contact with end surfaces of the filling film 542. Due to the recess formed in the fourth stage, the second end surfaces of the connection layer 550 can extend more than the first end surface of the connection layer 550. Thus, the first end surface and the second end surfaces of the connection layer 550 are offset from each other and can form a step profile.

During depositing the conductive material to form the connection layer 550, the conductive material is also formed on an inner surface of the hole 510 to form an outer layer 567 (e.g., the outer layer 167 of FIG. 2B) of a contact structure 560 (e.g., the contact structure 160 of FIG. 2B). In some implementations, the fifth stage of the example process also includes forming an inner layer 566 (e.g., the inner layer 166 of FIG. 2B) on the outer layer 567 and a body 565 (e.g., the body 165 of FIG. 2B) on the inner layer 566. The inner layer 566 can include a metallic material (e.g., W). In some implementations, the body 565 can include a conductive material, which can be same as the inner layer 566 or different from the inner layer 566. In some implementations, the body 565 includes an isolating material (e.g., oxide). The formed semiconductor structure 500e can be same as, or similar to, the semiconductor structure 250 of FIG. 2B.

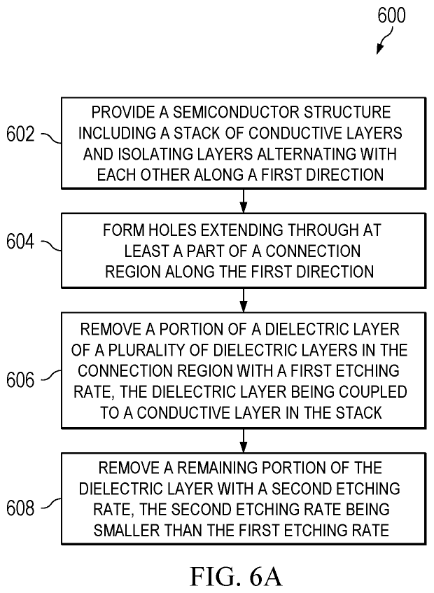

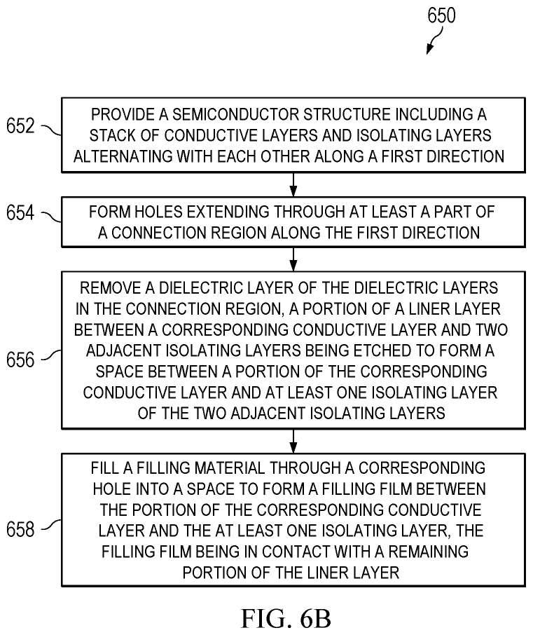

FIG. 6A is a flow chart of an example process 600 of forming a semiconductor structure. The semiconductor structure can be similar to, or same as, the semiconductor structure 100 of FIG. 1, the semiconductor structure 200 of FIG. 2A, the semiconductor structure 250 of FIG. 2B, the semiconductor structure 300 of FIG. 3A-3B, the semiconductor structure 400b of FIG. 4B, or the semiconductor structure 500e of FIG. 5E, or any intermediate structure thereof. The process 600 can include some or all of the fabrication process of forming the semiconductor structure with respect to FIGS. 4A-4B or FIGS. 5A-5E. The process 600 includes operations that can be performed with any suitable order and/or any combination.

At operation 602, a semiconductor structure is provided. The semiconductor structure includes a stack of conductive layers and isolating layers alternating with each other along a first direction (e.g., Z direction). The stack can be same as, or similar to, the stack 130 of FIG. 2A, FIG. 2B, FIG. 3A, FIG. 4A-4B, or FIG. 5A-5E. The conductive layers can be same as, or similar to, the conductive layers 130A of FIG. 2A, FIG. 2B, FIG. 3A, FIG. 4A-4B, or FIG. 5A-5E. The isolating layers can be same as, or similar to, the isolating layers 130B of FIG. 2A, FIG. 2B, FIG. 3A, FIG. 4A-4B, or FIG. 5A-5E. The semiconductor structure includes an array region and a connection region adjacent to the array region in a second direction perpendicular to the first direction. The array region can be same as, or similar to, the array region 100A of FIG. 1, FIG. 2A, or FIG. 2B, or the array region 402 of FIGS. 4A-4B, or the array region 502 of FIGS. 5A-5E. The connection region can be same as, or similar to, the connection region 100B of FIG. 1, FIG. 2A, or FIG. 2B, or the connection region 404 of FIGS. 4A-4B, or the connection region 504 of FIGS. 5A-5E. The semiconductor structure includes a plurality of dielectric layers (e.g., the dielectric layers 130C of FIG. 2A, FIG. 2B, FIG. 3A, FIG. 4A-4B, or FIGS. 5A-5E) and isolating layers (e.g., the isolating layers 130B of FIG. 2A, FIG. 2B, FIG. 3A, FIG. 4A-4B, or FIGS. 5A-5E) alternating with each other along the first direction in the connection region.

At operation 604, holes extending through at least a part of the connection region along the first direction are formed. The holes can be same as, or similar to, the holes 410 of FIGS. 4A-4B or the holes 510 of FIGS. 5A-5D. In some implementations, each conductive layer of the conductive layers of the stack is coupled to a respective hole of the holes through a corresponding one of the plurality of dielectric layers in the connection region, and is in contact with the corresponding one of the plurality of dielectric layers along a second direction (e.g., Y direction) perpendicular to the first direction.

At operation 606, a portion of a dielectric layer of the plurality of dielectric layers in the connection region is removed with a first etching rate, e.g., as illustrated in FIG. 5A. The dielectric layer is coupled to a portion (e.g., the portion 202 of FIG. 2A, the portion 204 of FIG. 2B, the portion 430 of FIG. 4A-4B, or the portion 530 of FIGS. 5A-5E) of a corresponding conductive layer in the stack. The portion of the corresponding conductive layer can be an end portion.

At operation 608, a remaining portion (e.g., the remaining portion 532 of FIG. 5B) of the dielectric layer with a second etching rate is removed, e.g., as illustrated in FIG. 5B. The second etching rate can be smaller than the first etching rate.

In some implementations, removing the portion of the dielectric layer includes using a first etching solution through a hole (e.g., the hole 410 of FIGS. 4A-4B or the hole 510 of FIGS. 5A-5D) corresponding to the dielectric layer. Removing the remaining portion of the dielectric layer includes using a second etching solution through the hole corresponding to the dielectric layer. In some examples, the dielectric layer includes a sacrificial dielectric material (e.g., SiN), and the second etching solution has a lower etching rate for the sacrificial dielectric material than the first etching solution.

In some implementations, the semiconductor structure includes a corresponding liner layer (e.g., the liner layer 133 of FIG. 2A, FIG. 2B, FIGS. 4A-4B, or FIGS. 5A-5E) between the conductive layer and two adjacent isolating layers. During removing the remaining portion of the dielectric layer using the second etching solution, a portion of the corresponding liner layer is etched to form a space (e.g., the space 432 of FIG. 4A or the space 524 of FIG. 5B) between the portion (e.g., the portion 430 of FIG. 4A-4B or the portion 530 of FIGS. 5A-5E) of the conductive layer and at least one isolating layer of the two adjacent isolating layers. In some examples, the corresponding liner layer includes a high-K dielectric material (e.g., Al₂O₃). The second etching solution can have a higher etching rate for the sacrificial dielectric material than for the high-K dielectric material.

In some implementations, the process 600 further includes: filling a filling material through the hole into the space to form a filling film (e.g., the filling film 210 of FIG. 2A, 220 of FIG. 2B, 440 of FIG. 4B, or 542 of FIGS. 5C-5E) between the portion of the conductive layer and the at least one isolating layer adjacent to the conductive layer. The filling film can be in contact with a remaining portion of the corresponding liner layer.

In some implementations, the filling material includes a conductive material (e.g., TiN). The process 600 can further include: filling the filling material through the hole to form a connection layer (e.g., the connection layer 180 of FIG. 2A or 450 of FIG. 4B) in a region (e.g., the space 420 of FIG. 4A) of the dielectric layer in the connection region and a first conductive layer (e.g., the outer layer 167 of FIG. 2A or 467 of FIG. 4B) on an inner surface of the hole, and forming a second conductive layer (e.g., the inner layer 166 of FIG. 2A or 466 of FIG. 4B) on the first conductive layer to form a contact structure corresponding to the hole. In some implementations, the process 600 further includes: forming a body (e.g., the body 165 of FIG. 2A or 465 of FIG. 4B) of the contact structure on the second conductive layer to fill the hole.

In some implementations, the filling material includes an isolating material (e.g., SiN). In some implementations, the isolating material includes a high-K dielectric material or the sacrificial dielectric material. The process 600 can further include: etching the filling material through the hole to expose an end surface of the conductive layer, e.g., as illustrated in FIG. 5D. In some implementations, during filling the filling material through the hole into the space to form the filling film, a filling layer (e.g., the layer 512 of FIG. 5C) is formed on an inner surface of the hole. The process 600 can further include: etching the filling material to remove the filling layer, e.g., as illustrated in FIG. 5D. A portion of the filling film in the space between the portion of the conductive layer and the at least one isolating layer adjacent to the conductive layer is removed during etching the filling material, e.g., as illustrated in FIG. 5D.

In some implementations, the process 600 further includes: forming a connection layer in the connection region (e.g., the connection layer 180 of FIG. 2B or 550 of FIG. 5E) in a region (e.g., the space 522 of FIG. 5B) of the dielectric layer in the connection region. The connection layer is in contact with the end surface of the conductive layer along the second direction and conductively coupled to the conductive layer. The connection layer is between the two adjacent isolating layers in the connection region. The process 600 can further include: forming a contact structure (e.g., the contact structure 160 of FIG. 2B, the contact structure 310, 312, or 314 of FIGS. 3A-3B, or the contact structure 560 of FIG. 5E) corresponding to the hole by forming at least one conductive layer (e.g., the layers 166, 167 of FIG. 2B or 566, 567 of FIG. 5E) on an inner surface of the hole and on the connection layer.

In some implementations, forming the contact structure includes: forming a body (e.g., the body 165 of FIG. 2B or 565 of FIG. 5E) of the contact structure on the at least one conductive layer in the hole by filling the isolating material in the hole. In some implementations, forming the at least one conductive layer includes: forming a first conductive layer (e.g., the outer layer 167 of FIG. 2B or 567 of FIG. 5E) on the inner surface of the hole and on the connection layer, and forming a second conductive layer (e.g., the inner layer 166 of FIG. 2B or 566 of FIG. 5E) on the first conductive layer. In some examples, the body includes an isolating material (e.g., oxide), the second conductive layer includes a metallic material (e.g., W), and the first conductive layer and the connection layer includes a same conductive material (e.g., TiN) different from the metallic material.

FIG. 6B is a flow chart of an example process 650 of forming a semiconductor structure. The semiconductor structure can be similar to, or same as, the semiconductor structure 100 of FIG. 1, the semiconductor structure 200 of FIG. 2A, the semiconductor structure 250 of FIG. 2B, the semiconductor structure 300 of FIG. 3A-3B, the semiconductor structure 400b of FIG. 4B, or the semiconductor structure 500e of FIG. 5E, or an intermediate structure thereof. The process 650 can include some or all of the fabrication process of forming the semiconductor structure with respect to FIGS. 4A-4B or FIGS. 5A-5E. The process 650 includes operations that can be performed with any suitable order and/or any combination.

At operation 652, a semiconductor structure is provided. The operation 652 can be same as, or similar to, operation 602 of FIG. 6A. The semiconductor structure includes a stack of conductive layers and isolating layers alternating with each other along a first direction (e.g., Z direction). The stack can be same as, or similar to, the stack 130 of FIG. 2A, FIG. 2B, FIG. 3A, FIG. 4A-4B, or FIG. 5A-5E. The conductive layers can be same as, or similar to, the conductive layers 130A of FIG. 2A, FIG. 2B, FIG. 3A, FIG. 4A-4B, or FIG. 5A-5E. The isolating layers can be same as, or similar to, the isolating layers 130B of FIG. 2A, FIG. 2B, FIG. 3A, FIG. 4A-4B, or FIG. 5A-5E. The semiconductor structure includes an array region and a connection region adjacent to the array region in a second direction perpendicular to the first direction. The array region can be same as, or similar to, the array region 100A of FIG. 1, FIG. 2A, or FIG. 2B, or the array region 402 of FIGS. 4A-4B, or the array region 502 of FIGS. 5A-5E. The connection region can be same as, or similar to, the connection region 100B of FIG. 1, FIG. 2A, or FIG. 2B, or the connection region 404 of FIGS. 4A-4B, or the connection region 504 of FIGS. 5A-5E. The semiconductor structure includes a plurality of dielectric layers (e.g., the dielectric layers 130C of FIG. 2A, FIG. 2B, FIG. 3A, FIG. 4A-4B, or FIGS. 5A-5E) and isolating layers (e.g., the isolating layers 130B of FIG. 2A, FIG. 2B, FIG. 3A, FIG. 4A-4B, or FIG. 5A-5E) alternating with each other along the first direction in the connection region.

At operation 654, holes extending through at least a part of the connection region along the first direction are formed. The operation 654 can be same as, or similar to, operation 604 of FIG. 6A. The holes can be same as, or similar to, the holes 410 of FIGS. 4A-4B or the holes 510 of FIGS. 5A-5D. In some implementations, each conductive layer of the conductive layers of the stack is coupled to a respective hole of the holes through a corresponding one of the plurality of dielectric layers in the connection region, and is in contact with the corresponding one of the plurality of dielectric layers along a second direction (e.g., Y direction) perpendicular to the first direction.

At operation 656, a dielectric layer of the plurality of dielectric layers in the connection region is removed. The operation 656 can be performed by the operations 606 and 608 of FIG. 6A. The dielectric layer can be coupled to a conductive layer in the stack. During removing the dielectric layer, a portion of a corresponding liner layer between the conductive layer and two adjacent isolating layers is etched to form a space (e.g., the space 432 of FIG. 4A or the space 524 of FIG. 5B) between an end portion (e.g., the portion 202 of FIG. 2A, the portion 204 of FIG. 2B, the portion 430 of FIGS. 4A-4B, or the portion 530 of FIGS. 5A-5E) of the conductive layer and at least one isolating layer of the two adjacent isolating layers.

In some implementations, removing the dielectric layer of the plurality of dielectric layers in the connection region includes: removing, using a first etching solution and through a hole corresponding to the dielectric layer, a portion of the dielectric layer of the plurality of dielectric layers in the connection region (e.g., as illustrated in FIG. 5A) and removing, using a second etching solution through the hole, a remaining portion (e.g., the portion 532 of FIG. 5A) of the dielectric layer that is in contact with the conductive layer in the connection region (e.g., as illustrated in FIG. 5B). The second etching solution has a lower etching rate for a sacrificial dielectric material (e.g., SiN) in the dielectric layer than the first etching solution. In some implementations, the corresponding liner layer includes a high-K dielectric material (e.g., Al₂O₃). The second etching solution has a higher etching rate for the sacrificial dielectric material than for the high-K dielectric material.

At operation 658, a filling material is filled through a hole corresponding to the dielectric layer into the space to form a filling film (e.g., the filling film 210 of FIG. 2A, 220 of FIG. 2B, 440 of FIG. 4B, or 542 of FIGS. 5C-5E) between the end portion of the conductive layer and the at least one isolating layer adjacent to the conductive layer. The filling film can be in contact with a remaining portion of the corresponding liner layer.

In some implementations, the filling material includes a conductive material (e.g., TiN). The process 600 can further include: filling the filling material through the hole to form a connection layer (e.g., the connection layer 180 of FIG. 2A or 450 of FIG. 4B) in a region (e.g., the space 420 of FIG. 4A) of the dielectric layer in the connection region and a first conductive layer (e.g., the outer layer 167 of FIG. 2A or 467 of FIG. 4B) on an inner surface of the hole, and forming a second conductive layer (e.g., the inner layer 166 of FIG. 2A or 466 of FIG. 4B) on the first conductive layer to form a contact structure corresponding to the hole. In some implementations, the process 650 further includes: forming a body (e.g., the body 165 of FIG. 2A or 465 of FIG. 4B) of the contact structure on the second conductive layer to fill the hole.

In some implementations, the filling material includes an isolating material (e.g., SiN). In some implementations, the isolating material includes a high-K dielectric material or the sacrificial dielectric material. The process 650 can further include: etching the filling material through the hole to expose an end surface of the conductive layer, e.g., as illustrated in FIG. 5D. In some implementations, during filling the filling material through the hole into the space to form the filling film, a filling layer (e.g., the layer 512 of FIG. 5C) is formed on an inner surface of the hole. The process 650 can further include: etching the filling material to remove the filling layer, e.g., as illustrated in FIG. 5D. A portion of the filling film in the space between the portion of the conductive layer and the at least one isolating layer adjacent to the conductive layer is removed during etching the filling material, e.g., as illustrated in FIG. 5D.

In some implementations, the process 650 further includes: forming a connection layer in the connection region (e.g., the connection layer 180 of FIG. 2B or 550 of FIG. 5E) in a region (e.g., the space 522 of FIG. 5B) of the dielectric layer in the connection region. The connection layer is in contact with the end surface of the conductive layer along the second direction and conductively coupled to the conductive layer. The connection layer is between the two adjacent isolating layers in the connection region. The process 600 can further include: forming a contact structure (e.g., the contact structure 160 of FIG. 2B, the contact structure 310, 312, or 314 of FIGS. 3A-3B, or the contact structure 560 of FIG. 5E) corresponding to the hole by forming at least one conductive layer (e.g., the layers 166, 167 of FIG. 2B or 566, 567 of FIG. 5E) on an inner surface of the hole and on the connection layer.

In some implementations, forming the contact structure includes: forming a body (e.g., the body 165 of FIG. 2B or 565 of FIG. 5E) of the contact structure on the at least one conductive layer in the hole by filling the isolating material in the hole. In some implementations, forming the at least one conductive layer includes: forming a first conductive layer (e.g., the outer layer 167 of FIG. 2B or 567 of FIG. 5E) on the inner surface of the hole and on the connection layer, and forming a second conductive layer (e.g., the inner layer 166 of FIG. 2B or 566 of FIG. 5E) on the first conductive layer. In some examples, the body includes an isolating material (e.g., oxide), the second conductive layer includes a metallic material (e.g., W), and the first conductive layer and the connection layer includes a same conductive material (e.g., TiN) different from the metallic material.

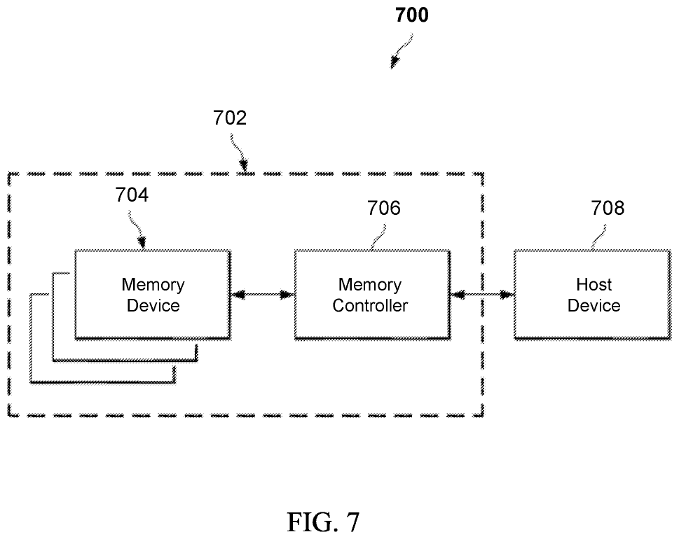

FIG. 7 illustrates a block diagram of a system 700 having one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, the system 700 can include a host device 708 and a memory system 702 having one or more 3D memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more 3D memory devices 704.

A 3D memory device 704 can be any 3D memory device disclosed herein. The 3D memory device can be formed by a 3D semiconductor structure, e.g., the 3D semiconductor structure 100 of FIG. 1, 200 of FIG. 2A, 250 of FIG. 2B, 300 of FIGS. 3A-3B, 400b of FIG. 4B, or 500e of FIG. 5E. In some implementations, a 3D memory device 704 includes a NAND Flash memory. Memory controller 706 (a.k.a., a controller circuit) is coupled to 3D memory device 704 and host device 708. Consistent with implementations of the present disclosure, 3D memory device 704 can include a plurality of conductive interconnections through a cover layer that are in contact with conductive pads in a conductive pad layer, and memory controller 706 can be coupled to 3D memory device 704 through at least one of the plurality of conductive interconnections. Memory controller 706 is configured to control 3D memory device 704. For example, memory controller 706 may be configured to operate a plurality of channel structures via word lines. Memory controller 706 can manage data stored in 3D memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program (or write) operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 7, memory controller 706 and a single 3D memory device 704 may be integrated into a memory system 702. Memory system 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +/−10%, +/−20%, or +/−30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a semiconductor structure comprising a stack of conductive layers and isolating layers alternating with each other along a first direction, wherein the semiconductor structure comprises an array region and a connection region adjacent to the array region in a second direction perpendicular to the first direction; and
contact structures extending through at least a part of the connection region along the first direction,
wherein a conductive layer of the stack is coupled to a contact structure of the contact structures through a connection layer in the connection region, wherein the conductive layer is in contact with the connection layer along the second direction, and wherein a filling film is in a space between a portion of the conductive layer and at least one isolating layer adjacent to the conductive layer.

2. The semiconductor device of claim 1, wherein the semiconductor structure comprises a corresponding liner layer between the conductive layer and two adjacent isolating layers including the at least one isolating layer,
wherein the filling film is in contact with the corresponding liner layer, and
wherein a filling material of the filling film is different from a material of the corresponding liner layer.

3. The semiconductor device of claim 1, wherein the connection layer comprises a conductive material, and the filling film comprises the conductive material.

4. The semiconductor device of claim 1, wherein the filling film comprises an isolating material, and wherein the isolating material comprises a high-K dielectric material.

5. The semiconductor device of claim 1, wherein the filling film is in contact with an end of the connection layer along the second direction, and
wherein the end of the connection layer comprises a first surface in contact with the conductive layer and a second surface in contact with the filling film, the first surface and the second surface being offset along the second direction.

6. The semiconductor device of claim 1, wherein the contact structure comprises at least one conductive layer and a body surrounded by the at least one conductive layer, and the connection layer is in contact with the at least one conductive layer at an end of the contact structure, and
wherein the at least one conductive layer comprises an inner layer in contact with the body and an outer layer in contact with the connection layer, and wherein the body comprises an isolating material, the inner layer comprises a metallic material, and the outer layer and the connection layer comprises a same conductive material different from the metallic material.

7. The semiconductor device of claim 1, wherein one of the contact structures is coupled to two or more of the conductive layers in the stack, and wherein the one of the contact structures comprises two or more conductive sections that are isolated from each other, and each of the two or more conductive sections is coupled to a respective one of the two or more of the conductive layers in the stack.

8. The semiconductor device of claim 1, wherein the semiconductor structure comprises a plurality of dielectric layers and isolating layers alternating with each other along the first direction in the connection region, and
wherein each of the contact structures extends through a respective set of dielectric layers and isolating layers in the connection region, and the connection layer is between two adjacent isolating layers in the connection region.

9. A method, comprising:
providing a semiconductor structure comprising a stack of conductive layers and isolating layers alternating with each other along a first direction, wherein the semiconductor structure comprises an array region and a connection region adjacent to the array region in a second direction perpendicular to the first direction, and the semiconductor structure comprises a plurality of dielectric layers and isolating layers alternating with each other along the first direction in the connection region;
forming holes extending through at least a part of the connection region along the first direction;
removing a portion of a dielectric layer of the plurality of dielectric layers in the connection region with a first etching rate, wherein the dielectric layer is coupled to a conductive layer in the stack; and
removing a remaining portion of the dielectric layer with a second etching rate, wherein the second etching rate is smaller than the first etching rate.

10. The method of claim 9, wherein removing the portion of the dielectric layer comprises using a first etching solution through a hole corresponding to the dielectric layer,
wherein removing the remaining portion of the dielectric layer comprises using a second etching solution through the hole corresponding to the dielectric layer, and
wherein the dielectric layer comprises a sacrificial dielectric material, and wherein the second etching solution has a lower etching rate for the sacrificial dielectric material than the first etching solution.

11. The method of claim 10, wherein the semiconductor structure comprises a corresponding liner layer between the conductive layer and two adjacent isolating layers,
wherein, during removing the remaining portion of the dielectric layer using the second etching solution, a portion of the corresponding liner layer is etched to form a space between a portion of the conductive layer and at least one isolating layer of the two adjacent isolating layers, and
wherein the corresponding liner layer comprises a high-K dielectric material, wherein the second etching solution has a higher etching rate for the sacrificial dielectric material than for the high-K dielectric material.

12. The method of claim 11, further comprising:
filling a filling material through the hole into the space to form a filling film between the portion of the conductive layer and the at least one isolating layer adjacent to the conductive layer, wherein the filling film is in contact with a remaining portion of the corresponding liner layer.

13. The method of claim 12, wherein the filling material comprises a conductive material, and the method further comprises:
filling the filling material through the hole to form a connection layer in a region of the dielectric layer in the connection region and a first conductive layer on an inner surface of the hole, and
forming a second conductive layer on the first conductive layer to form a contact structure corresponding to the hole.

14. The method of claim 12, wherein the filling material comprises an isolating material, and wherein the method further comprises:
etching the filling material through the hole to expose an end surface of the conductive layer.

15. The method of claim 14, further comprising:
forming a connection layer in the connection region in a region of the dielectric layer in the connection region, wherein the connection layer is in contact with the end surface of the conductive layer along the second direction and conductively coupled to the conductive layer, and the connection layer is between the two adjacent isolating layers in the connection region; and
forming a contact structure corresponding to the hole by forming at least one conductive layer on an inner surface of the hole and on the connection layer.

16. A method, comprising:
providing a semiconductor structure comprising a stack of conductive layers and isolating layers alternating with each other along a first direction, wherein the semiconductor structure comprises an array region and a connection region adjacent to the array region in a second direction perpendicular to the first direction, and the semiconductor structure comprises a plurality of dielectric layers and isolating layers alternating with each other along the first direction in the connection region;
forming holes extending through at least a part of the connection region along the first direction;
removing a dielectric layer of the plurality of dielectric layers in the connection region, wherein the dielectric layer is coupled to a conductive layer in the stack, and wherein, during removing the dielectric layer, a portion of a corresponding liner layer between the conductive layer and two adjacent isolating layers is etched to form a space between a portion of the conductive layer and at least one isolating layer of the two adjacent isolating layers; and
filling a filling material through a hole corresponding to the dielectric layer into the space to form a filling film between the portion of the conductive layer and the at least one isolating layer adjacent to the conductive layer, wherein the filling film is in contact with a remaining portion of the corresponding liner layer.

17. The method of claim 16, wherein removing the dielectric layer of the plurality of dielectric layers in the connection region comprises:
removing, using a first etching solution and through a hole corresponding to the dielectric layer, a portion of the dielectric layer of the plurality of dielectric layers in the connection region; and
removing, using a second etching solution through the hole, a remaining portion of the dielectric layer that is in contact with the conductive layer in the connection region, wherein the second etching solution has a lower etching rate for a sacrificial dielectric material in the dielectric layer than the first etching solution.

18. The method of claim 16, further comprising:
forming a connection layer in the connection region in a region of the dielectric layer in the connection region, wherein the connection layer is in contact with an end surface of the conductive layer along the second direction and conductively coupled to the conductive layer, and the connection layer is between the two adjacent isolating layers in the connection region.

19. The method of claim 18, wherein the filling material comprises a conductive material, and the method further comprises:
filling the filling material through the hole to form the connection layer in the region of the dielectric layer in the connection region and a first conductive layer on an inner surface of the hole, and
forming a second conductive layer on the first conductive layer to form a contact structure corresponding to the hole.

20. The method of claim 18, wherein the filling material comprises an isolating material, and wherein the method further comprises:
etching the filling material through the hole to expose the end surface of the conductive layer.
